(19) United States
(12) Patent Application Publication
(10) Pub. No.: US 2007/0139741 A1
(43) Pub. Date: Jun. 21, 2007

(54) User interface device, method of displaying preview image, and computer program product

(76) Inventors: Junichi Takami, Kanagawa (JP); Tetsuya Sakayori, Tokyo (JP); Iwao Saeki, Kanagawa (JP); Haruo Shida, Kanagawa (JP); Takashi Yano, Tokyo (JP); Yoshifumi Sakuramata, Tokyo (JP); Takanori Nagahara, Kanagawa (JP); Hiroko Mano, Tokyo (JP)

Correspondence Address: COOPER & DUNHAM, LLP, 1185 AVENUE OF THE AMERICAS, NEW YORK, NY, 10036, US

(21) Appl. No.: 11/637,448

(22) Filed: Dec. 11, 2006

(30) Foreign Application Priority Data
Dec. 15, 2005 (JP) 2005-362189
Oct. 26, 2006 (JP) 2006-290892

(51) Int. Cl. G03F 3/10

(52) U.S. Cl. 358/527; 358/538

(57) ABSTRACT

An operation displaying unit displays thereon a preview image of an input image and receives a specification of a position on displayed preview image. An item selecting unit selects at least two process items corresponding to a display position of the displayed preview image based on specified position on the displayed preview image. A preview generating unit generates a new preview image obtained by performing selected at least two processes on the input image. A preview displaying unit displays generated preview image on the operation displaying unit in a menu format.

### CROSS-REFERENCE TO RELATED APPLICATIONS

The present document incorporates by reference the entire contents of Japanese priority document, 2005-362189 filed in Japan on Dec. 15, 2005 and 2006-290892 filed in Japan on Oct. 26, 2006.

### BACKGROUND OF THE INVENTION

1. Field of the Invention

The present invention relates to a user interface device, a method of displaying a preview image, and a computer program product.

2. Description of the Related Art

Conventionally, in image processing apparatuses, such as copiers, facsimiles, and printers, a user selects a function desired to be executed from out of functions of an image processing apparatus, and sets the function as desired. For example, the apparatus is configured to receive settings, including those regarding the type and state, such as density, of a document, those regarding various image processing, such as image zooming, single-sided/double-sided printing, and setting margin size, and those regarding post-processing, such as sorting, stapling, and hole punching.

To let the user set these various settings, the conventional image processing apparatus provides many setting items, and the user has to perform a setting operation so as to obtain an intended process result from out of these many stetting items.

However, in the conventional image processing apparatus, a final process result that will be obtained from the setting, for example, a printing result, cannot be known until an actual printout is obtained, thereby often leading to an unexpected finish.

To get around this problem, a preview displaying apparatus has been suggested that displays a preview image indicative of the state of a print result (see Japanese Patent Application Laid-Open No. 2003-5471). Also, an image processing apparatus has been suggested that displays a preview image in a state where image data is printed on a sheet corresponding to a piece of sheet image data selected from out of pieces of sheet image data with different sheet qualities (see Japanese Patent Application Laid-Open No. 2002-103726). Furthermore, an image forming system has been suggested that combines a plurality of pieces of edited image data for preview display (see Japanese Patent Application Laid-Open No. H11-234503).

In these conventional technologies, images obtained as the process results of image processing according to settings are displayed one by one or in a combined manner for preview display. By performing operations, such as viewing preview and image(s) and performing a resetting operation, a finish state is checked before printout to perform a setting operation, thereby obtaining an intended image output.

According to the above literatures, the processes based on the set items have to be performed to cause a preview display for a try. However, when the number of setting items is large, many operations have to be performed by trial and error until a desired preview image is displayed.

### SUMMARY OF THE INVENTION

It is an object of the present invention to at least partially solve the problems in the conventional technology.

A user interface device according to one aspect of the present invention includes an operation displaying unit that displays thereon a preview image of an input image and receives a specification of a position on displayed preview image; an item selecting unit that selects at least two process items corresponding to a display position of the displayed preview image based on specified position on the displayed preview image; a preview generating unit that generates a new preview image obtained by performing selected at least two processes on the input image; and a preview displaying unit that displays generated preview image on the operation displaying unit in a menu format.

A method of displaying a preview image according to another aspect of the present invention includes receiving a specification of a position on a preview image of an input image displayed on an operation displaying unit; selecting at least two process items corresponding to a display position of displayed preview image based on specified position on the displayed preview image; generating a new preview image obtained by performing selected at least two processes on the input image; and displaying generated preview image on the operation displaying unit in a menu format.

A computer program product according to still another aspect of the present invention includes a computer usable medium having computer readable program codes embodied in the medium that when executed cause a computer to execute receiving a specification of a position on a preview image of an input image displayed on an operation displaying unit; selecting at least two process items corresponding to a display position of displayed preview image based on specified position on the displayed preview image; generating a new preview image obtained by performing selected at least two processes on the input image; and displaying generated preview image on the operation displaying unit in a menu format.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a functional block diagram of an image forming apparatus having incorporated therein a user interface device according to a first embodiment of the present invention;

FIG. 2A is a schematic drawing of one example of a preview image displayed by an operation displaying unit of the user interface device;

FIG. 2B is a schematic drawing of one example of a relation table for use by an item selecting unit;

FIG. 3 is a schematic drawing that depicts one example in which names of processes selected by specifying a split area and split preview images after process are concurrently on menu display;

FIG. 4A is a schematic drawing of a preview image after hole punching;

FIG. 4B is a schematic drawing of a preview image after binding margin adjustment;

FIG. 5 is a schematic drawing of another example of split preview images;

FIG. 6 is a schematic drawing of still another example of split preview images;

FIG. 7 is a table of one example of a design of windows of split preview images;

FIG. 8 is a drawing for explaining arrangement of the windows of the split preview images;

FIG. 9 is a flowchart of a procedure of displaying split preview images according to the first embodiment;

FIG. 10 is a flowchart of a procedure of displaying split preview images according to a second embodiment of the present invention;

FIG. 11 is a functional block diagram of an image forming apparatus having incorporated therein an user interface device according to a third embodiment of the present invention;

FIG. 12 is a flowchart of a procedure of displaying split preview images according to the third embodiment; and

FIG. 13 is a block diagram of a hardware configuration of an image forming apparatus having incorporated therein the user interface device according to the present invention.

### DETAILED DESCRIPTION OF THE PREFERRED EMBODIMENTS

Exemplary embodiments according to the present invention will be explained in detail below with reference to the accompanying drawings.

A user interface device according to a first embodiment of the present invention receives a specification of a position through a preview image of input information, and displays process items indicative of possible processes on an area corresponding to a specified position and preview images subjected to these processes are displayed in a menu format. With this configuration, only with an operation of specifying a position, a plurality of process items indicative of possible processes associated with the specified area and preview images of a processed area subjected to these processes can be on menu display, thereby providing a user interface device with excellent operability.

Also, through a menu displayed on an operation displaying unit; a specification of a process item is received, and the specified process is performed on the input information, thereby further displaying a preview image after process.

When a specification of a position is received, a plurality of processes may be performed on either of the entire preview image of the input information and a trimming area for menu display.

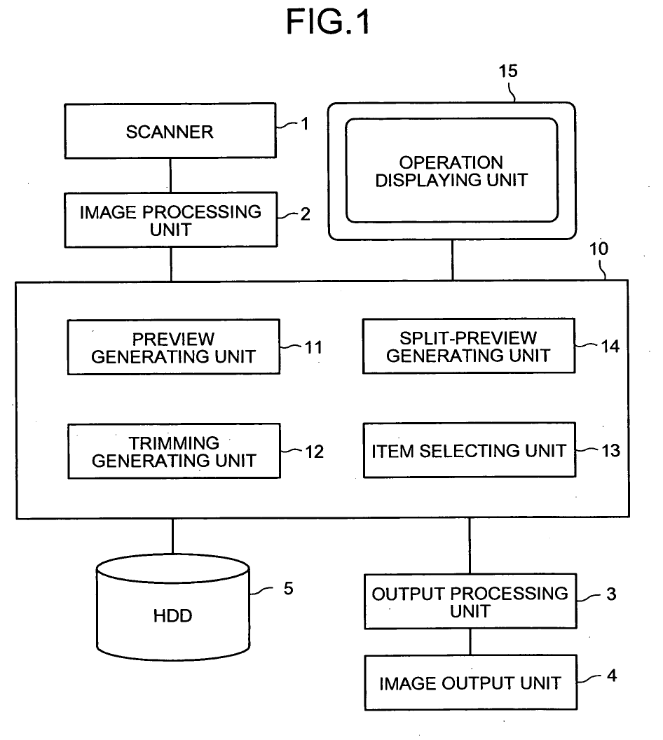

FIG. 1 is a functional block diagram of an image forming apparatus having incorporated therein the user interface device according to the first embodiment. The image forming apparatus includes a scanner 1, an image processing unit 2, an output processing unit 3, an image output unit 4, a memory (hard disk drive (HDD)) 5, and a user interface device 10.

The scanner 1 reads a document image. The scanner 1 irradiates a document moving in a sub-scanning direction with reading light, and performs optical-electrical conversion with an optical-electrical converting element, such as a Charge Coupled Device (CCD), thereby reading the document image. When an Auto Document Feeder (ADF) that feeds a plurality of sheets of a document one by one is provided, the scanner 1 sequentially reads the sheets of the document fed from the ADF as analog image data, and then transmits the analog data to the image processing unit 2.

The image processing unit 2 receives the analog data obtained through reading by the scanner 1, converts it to digital image data for output to the HDD 5, and transmits the digital image data to the user interface device 10.

The HDD 5 is an image storage unit, classifying the image data obtained through reading by the scanner 1 by file for storage. The HDD 5 can be substituted with a large-capacity random access memory (RAM).

The user interface device 10 receives an input of the image information obtained through reading by the scanner 1, displays it as a preview image. When an area is specified, process items indicative of possible processes in that area and partial preview image subjected to these processes are on menu display in association with each other. Also, when a process item is specified through this menu display, this process is performed on the input information, and an entire preview display is displayed.

The output processing unit 3 performs an output process on the input image data based on the process settings received by the user interface device 10. Also, the output processing unit 3 performs various required image processes, such as gamma conversion, on the input image data. The image output unit 4 produces an image output according to the settings in the output process performed by the output processing unit 3. Here, the output process performed by the image output unit 4 includes not only a process of forming an image on an output sheet for image output but also a post-printing process, such as stapling or hole punching.

The user interface device 10 according to the first embodiment includes a preview generating unit 11, a trimming generating unit 12, and an item selecting unit 13, a split-preview generating unit 14, and an operation displaying unit 15. The preview generating unit 11, the trimming generating unit 12, and the split-preview generating unit 14 form a preview generating portion.

The preview generating unit 11 generates preview image information for displaying input information, and area icon information indicative of split areas obtained by splitting a preview image. The preview image is generated by, for example, decimating the input image information so that the information has an amount of information only for display on the operation displaying unit 15.

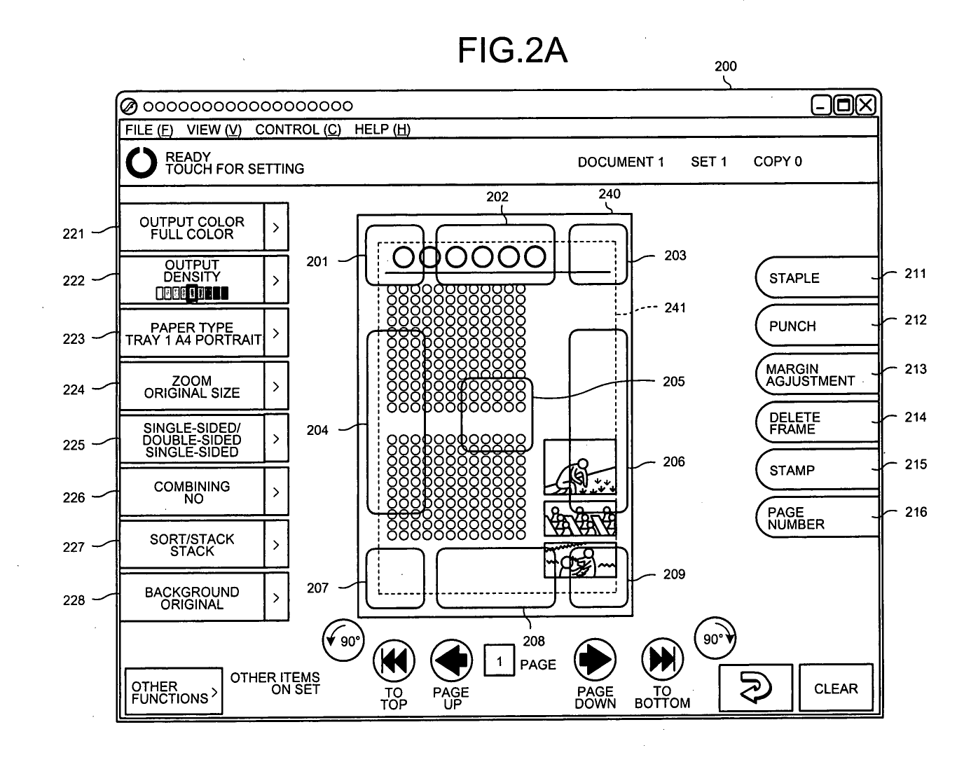

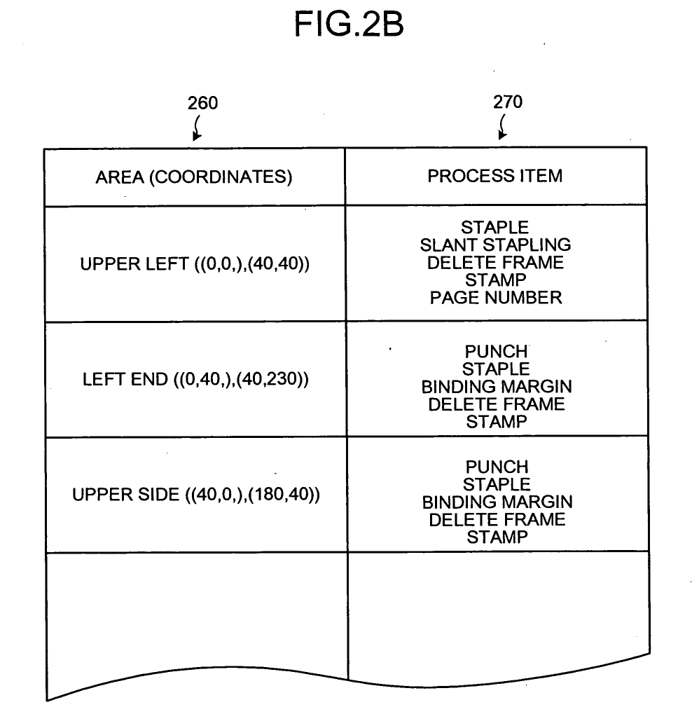

FIG. 2A is a schematic drawing of one example of a preview image displayed by the operation displaying unit 15 of the user interface device. The preview generating unit 11 splits a preview image into nine, that is, three in a vertical direction by three in a horizontal direction. Then, the preview generating unit 11 generates area icon information for displaying split areas 201 to 209 as area icons.

The trimming generating unit 12 generates information about the split areas obtained through splitting by the preview generating unit 11. This information is for displaying on the operation displaying unit 15 the split areas obtained through splitting the preview image into nine by the preview generating unit 11.

The trimming generating unit 12 may literally spilt input information into plural pieces, may determine a trimming with overlapping areas, or may trim the entire initial preview image.

On the operation displaying unit 15, based on the preview image information and the area icon information generated by the preview generating unit 11, a preview image 240 and area icons 201 to 209 are displayed. This achieves a preview displaying portion. Also, the operation displaying unit 15 receives a specification of a split area through a touch input from any of the displayed area icons 201 to 209.

The operation displaying unit 15 can be configured by using a liquid crystal display or the like, for example, with a touch panel being disposed on an upper portion of a liquid crystal monitor. The operation displaying unit 15 has various operation keys and a touch panel disposed on a finished image displaying portion (for example, a liquid crystal display). Through the operation keys and touch panel, various operations required for operating the image processing apparatus. In particular, various setting operations are received, such as image processing on a document image desired by the user to be printed, settings regarding printing conditions, and settings regarding post-processing.

As shown in FIG. 2A, the operation displaying unit 15 has, as various process items indicative of processes to be performed on the input information, staple 211, punch 212, adjust biding, margin 213, delete frame 214, stamp 215, and page number 216 displayed on the right side of a screen.

The operation displaying unit 15 has process items of output color 221, output density 222, paper 223, zoom 224, single sided/double-sided 225, combining 226, sort/stack 227, and background 228 displayed on the left side of the screen.

The item selecting unit 13 selects a process item indicative of a process to be performed on the input information, in an area corresponding to an area icon specified through any one of the area icons 201 to 209 displayed on the operation displaying unit 15.

FIG. 2B is a schematic drawing of one example of a relation table for use by the item selecting unit 13. This relation table has areas and process items defined in association with each other. Each area is defined by coordinates for displaying a diagonal line between two points, and is defined as a rectangle parallel to main and sub-scanning directions with a line segment between these two points as a diagonal line. For example, “upper left (0, 0), (40, 40)” defines a rectangular area with four points (0, 0), (0, 40), (40, 0) and (40, 40). When an input that specifies a position is detected in this rectangle, process items listed on the right of the table including staple, slant stapling, delete frame, stamp, and page number are selected.

When an area icon receives a touch input, a coordinate position as input information is determined, and the process items corresponding to the area defined by the coordinate position on the relation table depicted in FIG. 2B are retrieved and read. Also, when a area at a “left end” is touched for input, the item selecting unit 13 refers to the relation table depicted in FIG. 2B to read, as process items, punch, staple, binding margin, delete frame, and stamp. On the other hand, there is a case of not selecting any process item when, for example, an area at “upper left” is touched for input. In that case, hole punching is not specified in the relation table. Therefore, when referring to the relation table, the item selecting unit 13 does not select an item for hole punching.

Alternatively, the configuration can be such that the preview generating unit 11 does not generate area icon information and the item selecting unit 13 selects a process item from an area where the operation displaying unit 15 receives a position specification.

The split-preview generating unit 14 performs the process of each item selected by the item selecting unit 13 on the split-area information of the preview image 240. Then, the process item and a split preview image obtained by performing the process on the split area are concurrently on menu display as a trimming image.

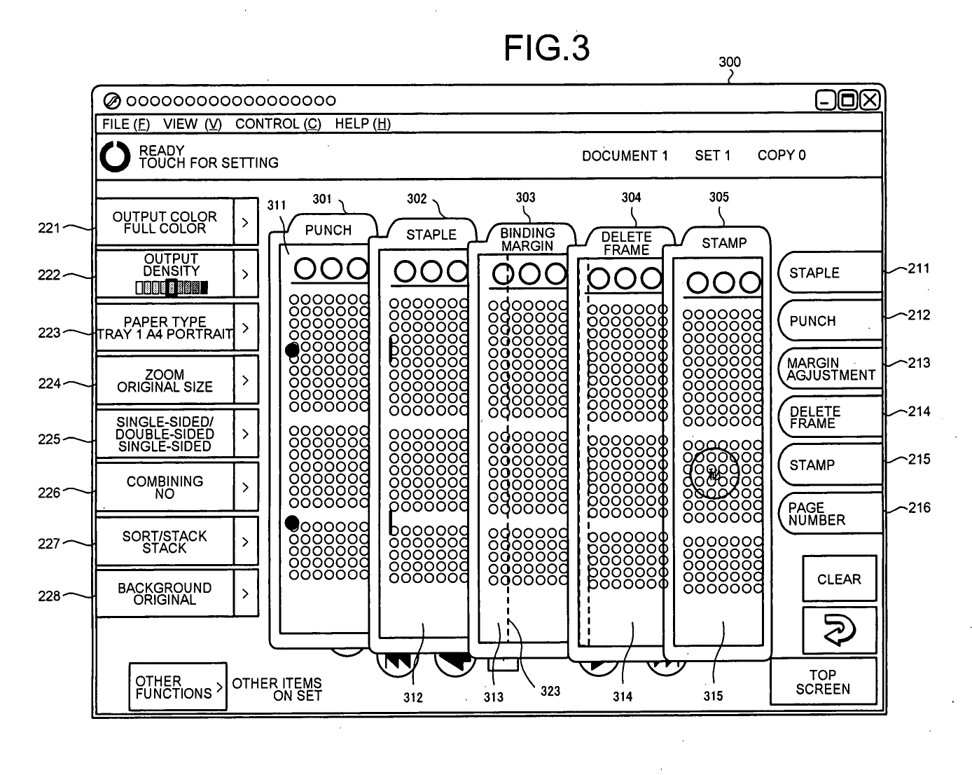

FIG. 3 is a schematic drawing that depicts one example in which names of processes selected by specifying a split area and split preview images after process are concurrently on menu display. In FIG. 3, a split area is specified by touching any of the area icons 204 for input. Then, possible processes in this split area are selected, and their names and split preview images after process are concurrently on menu display. In FIG. 3, hole punching as a process item is displayed in a form of a tag 301 and a split preview image 311 based on the split preview image information generated with the specified split area subjected to hole punching are displayed.

Similarly, a tag 302 indicative of staple as a process item and a split preview image 312 subjected to stapling are displayed. Similarly, as for binding margin, delete frame, and stamp, tags 303 to 305 indicative of the respective process items and spilt preview images 313 to 315 subjected to the respective processes are displayed.

When the operator views the split preview image 311 subjected to hole punching and displayed with the tag 301, the operator can visually recognize that punch holes interfere with a document image portion and some information will be lost if the image is output as it is. Therefore, the operator will realize the necessity of binding margin adjustment.

The operator selects the “adjust binding margin” item, and moves through touch input a dotted line 323 representing a binding margin in the image to the right. With this operation, a moving operation is performed, in which the document portion read in the trimming image is moved to the right to avoid the positions of the punch holes, thereby preventing the inconvenience of the punch holes intervening the document information.

As for process items, such as “adjust binding margin” and “delete frame”, causing the document image to be changed by specifying dimensions after menu selection, an illustration that makes the process easy to understand is desired for display in each split preview image.

A frame is a black frame undesirably read into the outside of the document when, for example, a thick document is read by the scanner 1 and a pressing plate of a reading unit hovers due to the thickness of the document. The process item of “delete frame” is to delete such a black frame through image processing.

In this manner, depending on the process, when a specific image is deleted or when a process of moving a document portion due to binding margin adjustment is performed, for example, it is preferable that the process result be immediately reflected upon the trimming image. By contrast, it is preferable that a process, such as hole punching, be not reflected upon the trimming image because the image with such a process being reflected thereon is difficult to distinguish from another image obtained through, for example, stapling.

When the trimming generating unit 12 trims the entire preview image, the processes may be performed on the entire preview image, and preview images obtained through the processes may overlap one another for display.

When an input for determining selection through, for example, double clicking on the screen, the preview generating unit 11 generates preview image information again with the set amount of binding margin for display on the operation displaying unit 15.

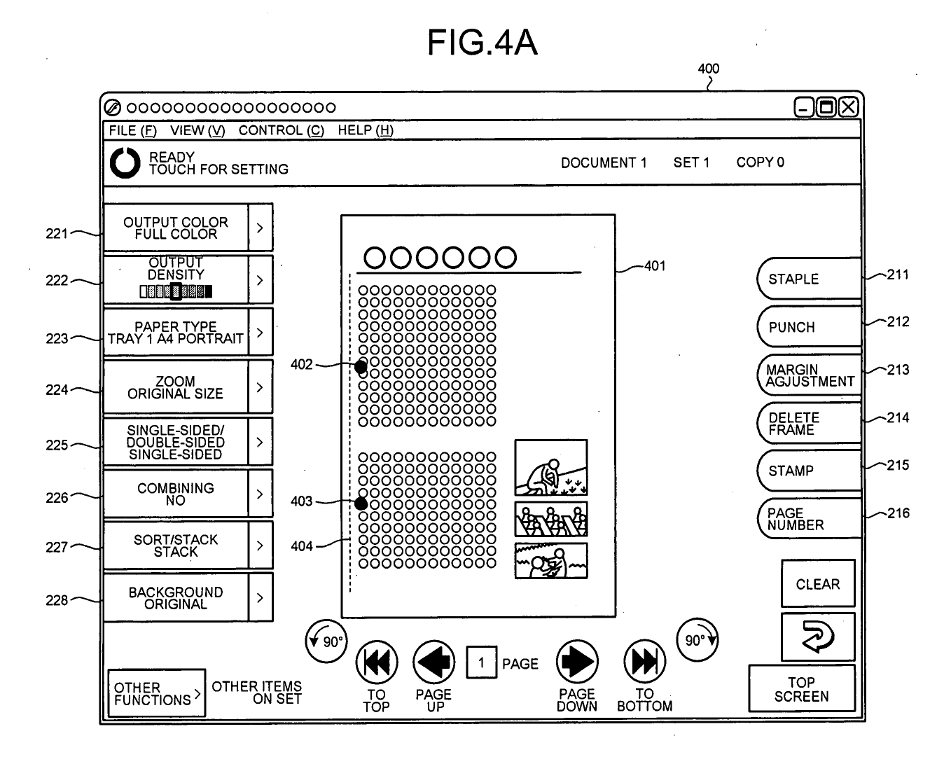

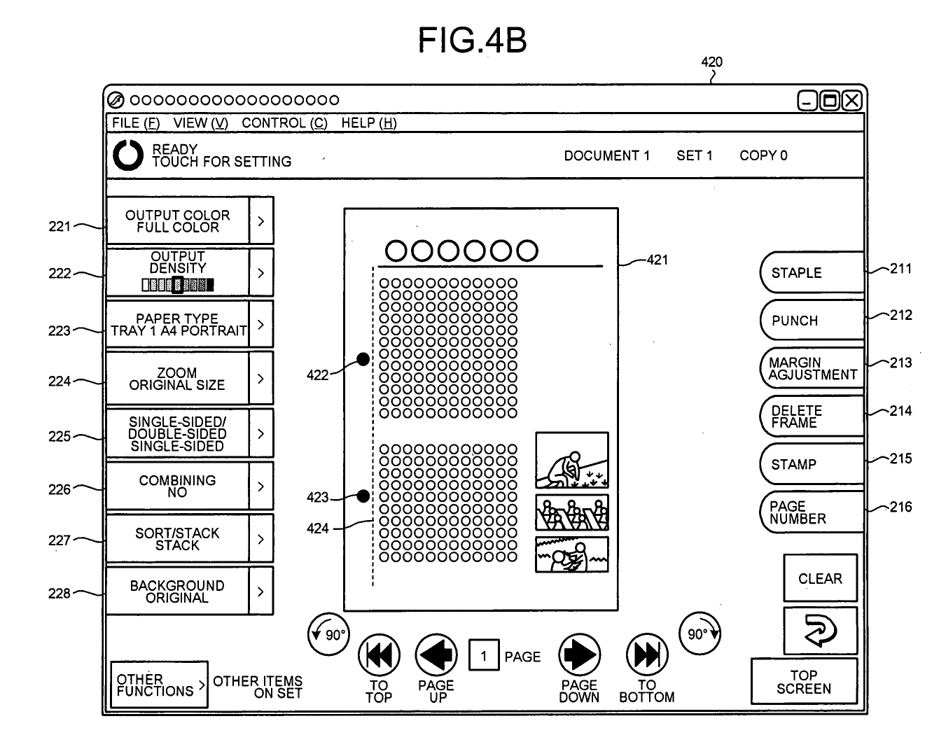

FIG. 4A is a schematic drawing of a preview image after hole punching. The configuration can be such that, when hole punching is set through the split preview image, the display is returned to a display of the entire preview image. In the drawing, it can be visually recognized that punch holes 402 and 403 interfere with a binding margin line 404.

FIG. 4B is a schematic drawing of a preview image after binding margin adjustment. With the touch input through the trimming image of binding margin on the menu display depicted in FIG. 3, the position of the document information is shifted to avoid interference with the punch holes. The binding margin can be set not only by setting through a menu display, but also by calling the menu depicted in FIG. 3 through “adjust binding margin” 213 of the process items displayed concurrently on the right end on the screen displayed in FIG. 4A. In this manner, it can be visually recognized that punch holes 422 and 423 and a binding margin line 424 are set so as not to interfere with each other.

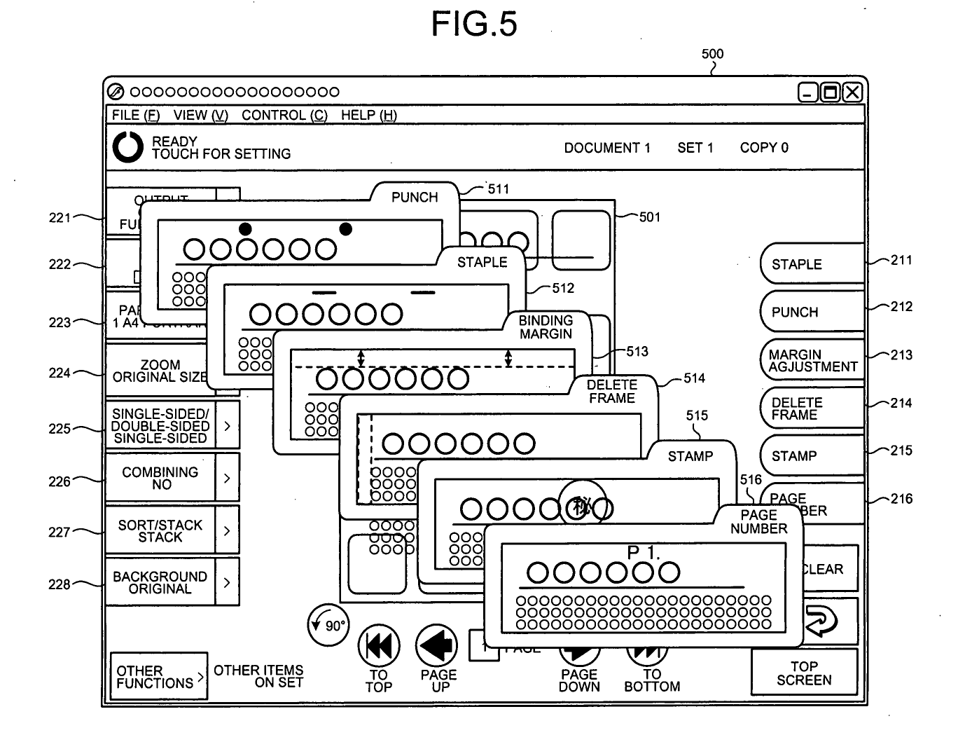

FIG. 5 is a schematic drawing of another example of split preview images. In FIG. 5, through a specification input through the area icon 202 indicative of an upper side depicted in FIG. 2A, names of processes selected in association in the relation table of FIG. 2B and split preview images after processes are concurrently displayed. Here, the area is an upper-side area on the screen, and the process items are punch 511, staple 512, binding margin 513, delete frame 514, stamp 515, and page number 516.

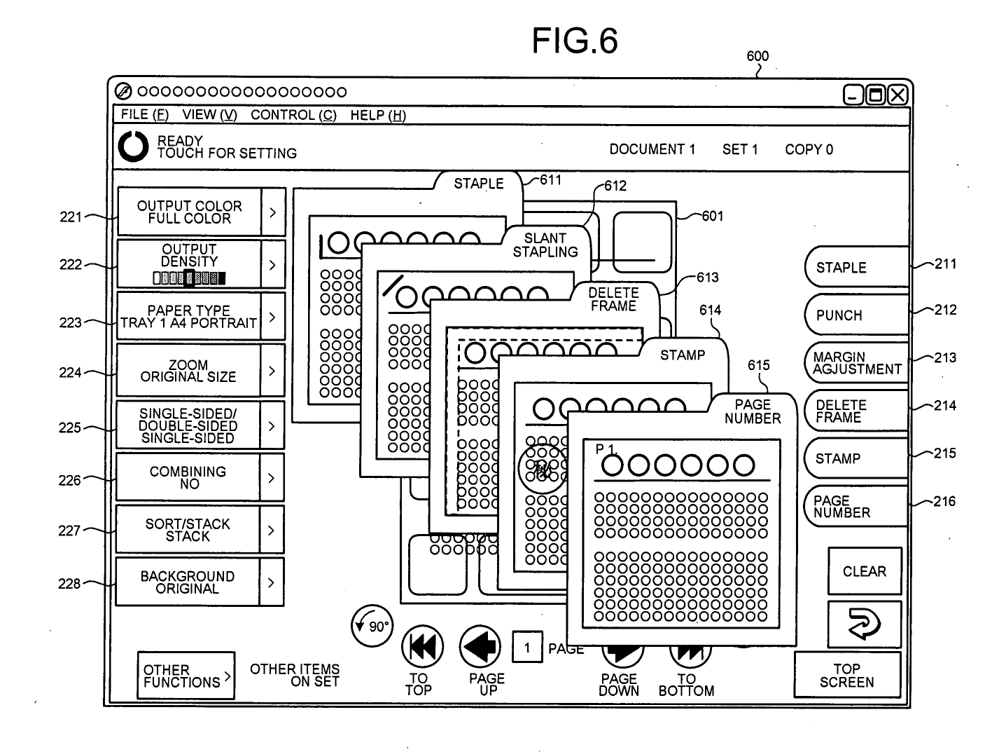

FIG. 6 is a schematic drawing of still another example of split preview images. The area icon 201 is selected to specify a corresponding split area on the upper left of the screen, and process items including staple 611, slant stapling 612, delete frame 613, stamp 614, and page number 615 and split preview images subjected to processes of the respective process items are concurrently displayed.

In this manner, the split preview images are preferably displayed so as to partially overlap in a sequential manner in a predetermined direction. This is because, with these split preview images being displayed so as not to be too large or too small but to be aesthetic in perspective, each split area after the process can be easy to visually recognize.

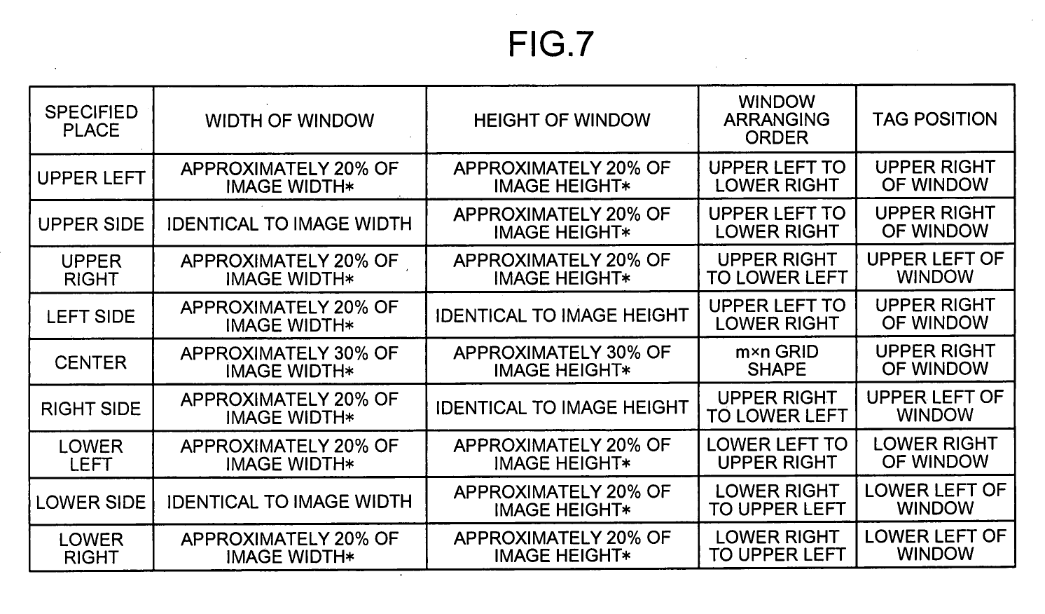

FIG. 7 is a table that depicts one example of a design of windows of split preview images. The size of a menu display window with a split preview image is appropriately set according to the size of the entire preview image and a touched position, so that a position on which attention should be focused is reliably displayed. Also, the sequence of superposing the windows and the position of a tag representing a function name attached to the window are set in a similar manner. FIG. 7 depicts merely an example of standards for setting in this manner, but is not meant to be restrictive.

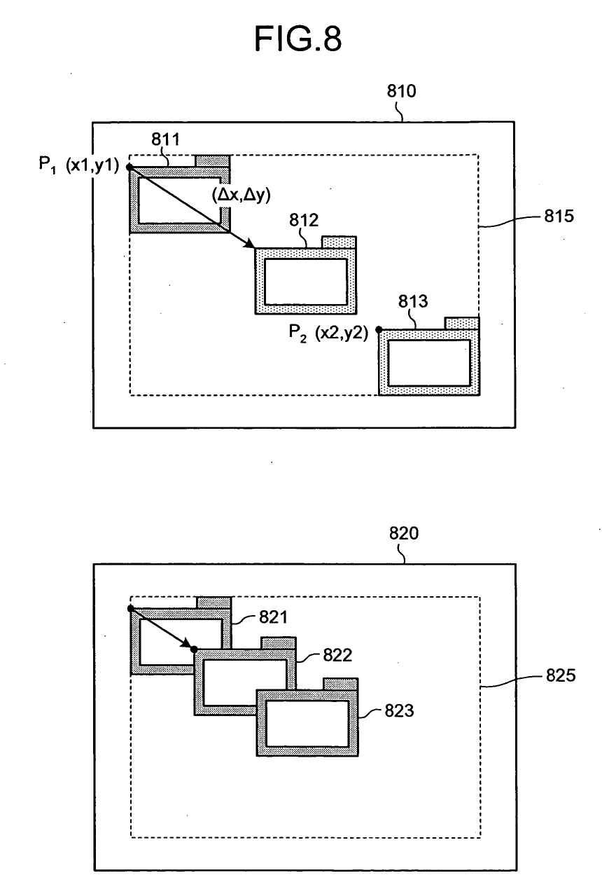

FIG. 8 is a drawing for explaining arrangement of windows of the split preview images. The display positions of the plural windows are determined based on, for example the following rule.

(1) For a first window display position, according to the position of the specified area, a position P1 (x1, y1) is found where one of the left side and the right side and one of the upper side and the lower side are each in contact with one corresponding side of a menu display area, and the widow is displayed at the found position (window 811).

(2) According to the number of items in the menu, a position P2 (x2, y2) is found where the last window is in contact with a side opposite to the side mentioned in (1). However, at this point, no display is produced (window 813 although not displayed).

(3) According the first window and the last window and the number of items in the menu, a shift width (Δx, Δy) between adjacent windows is calculated.

(4) The size of the shift width is calculated through the square root of (Δx)2+(Δy)2. If this shift width exceeds a predetermined upper limit value, the shift width is set to be equal to the upper limit value.

(5) According to the finally-determined shift amount, the second window and onward are displayed as sequentially overlapping (windows 821, 822, and 823). Here, tags and the shift amount are preferably set to prevent the tags from being hidden.

If the all process items are tried to be displayed all at once, there may be the case where too many overlapping portions of the windows appear due to many process items. In this case, the split preview image in each window does not function as a preview. To get around this problem, an upper limit of the number of windows to be displayed on one screen is provided, and a display indicative of the presence of a previous candidate/next candidate and an operation of switching to the previous candidate/next candidate can be performed. As for previous candidates/next candidates that overflow from the screen, only their function names may be displayed.

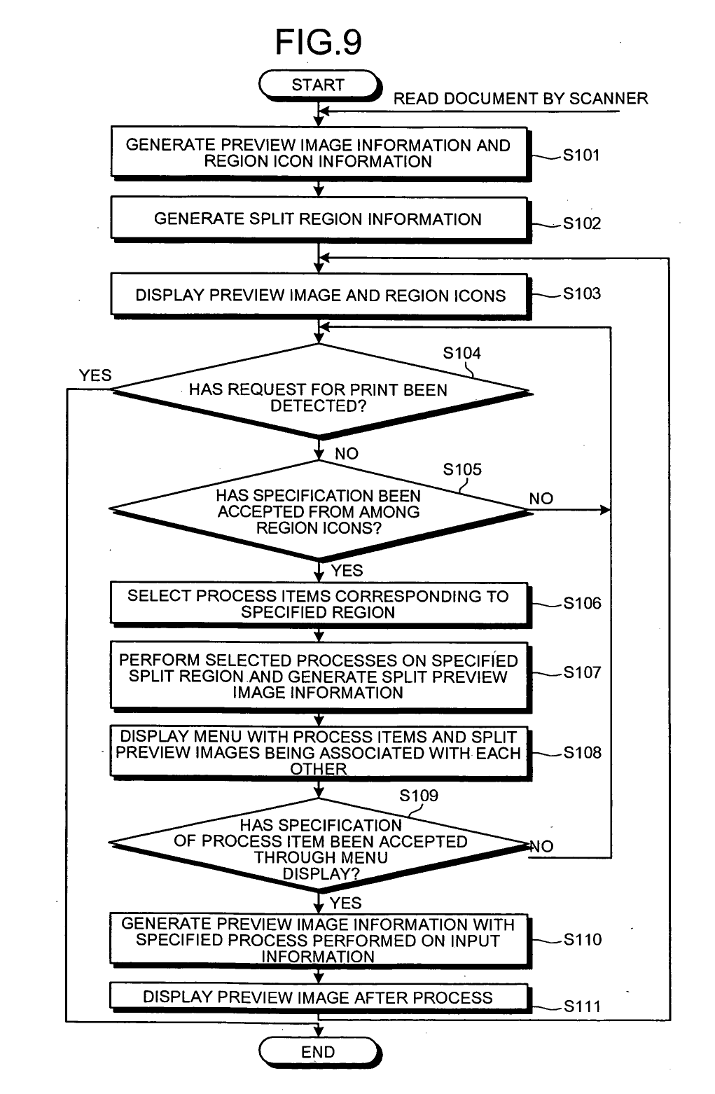

FIG. 9 is a flowchart for explaining a procedure of displaying split preview images according to the first embodiment. Image information read by the scanner 1 is digitally-converted by the image processing unit 2. The preview generating unit 11 generates, for this input information, preview image information indicative of an entire display of each sheet of the document and area icon information indicative of split areas obtained by splitting the preview image. That is, information for displaying the preview image 240 and the area icons 201 to 209 depicted in FIG. 2A is generated (step S101).

The trimming generating unit 12 generates split-area information about the split areas split by the preview generating unit 11 (step S102). In the first embodiment, the split-area information is generated after the preview image information is generated.

The operation displaying unit 15 displays the preview image 240 and the area icons 201 to 209 (step S103).

The operation displaying unit 15 is in a state or receiving and detecting a request for print (step S104). Upon detection of such a request (“Yes” at step S104), the procedure ends for printing.

If the operation displaying unit 15 does not receive or detect a request signal for print (“No” at step S104), the operation displaying unit 15 is ready for receiving a specification of an area from among the displayed area icons 201 to 209 (step S105). If the operation displaying unit 15 does not receive a specification from among area icons 201 to 209 (“No” at step S105), the procedure returns to step S104.

If the operation displaying unit 15 has received a specification of an area icon from among the displayed area icons 201 to 209 (“Yes” at step S105), the item selecting unit 13 searches the relation table depicted in FIG. 2B based on the area as the input information to read corresponding process items. By referring to the relation table depicted in FIG. 2B, the item selecting unit 13 reads punch, staple, binding margin, delete frame, and stamp as process items at input coordinates. On the other hand, in the relation table, in the upper-left area, for example, hole punching is not specified, and therefore hole punching is not selected at the time of reference (step S106).

The split-preview generating unit 14 performs selected processes on the split-area information corresponding to the specification of the area icon, and generates split preview image information on which split area images after these processes are based (step S107).

The operation displaying unit 15 displays a menu with the process items and the split preview images being associated with each other. In particular, as shown in FIGS. 3, 5, and 6, a preferable display format is such that each split preview image is surrounded by a frame and part of the frame protrudes for displaying the name of the process item (step S108). In this manner, the process items associated with the area and the split preview images obtained by performing processes indicated by these process items on the specified split-area information and attached with the process items are concurrently displayed.

The operation displaying unit 15 is ready for receiving a specification of a process item through a touch input by the operator (step S109). If the operation displaying unit 15 does not receive such a specification (“No” at step S109), the procedure returns to step S104. If the operation displaying unit 15 has received such a specification (“Yes” at step S109), the split-preview generating unit 14 performs the specified process on the entire input information and further generates preview image information after process (step S110). As shown in FIG. 4B, for example, the split-preview generating unit 14 causes the operation displaying unit 15 to generate, for example, a preview image for hole punching after binding margin adjustment (step S110).

In this manner, according to the user interface device of the first embodiment, a specification of an area icon from among the area icons 201 to 209 each representing a split area is received through a preview image display of input information, and possible process items in the specified split area and preview images of the split areas subjected to processes indicated by these process items are displayed. Thus, with only an operation of specifying an area, possible process items in the specified area and split preview images after process with the processes indicated by the process items being performed on the split area can be displayed. With this, a user interface device with high operability can be achieved.

Also, a specification of a process item is received through a process menu displayed on the operation displaying unit 15, the specified process is performed on the entire input information, and an overall preview image for each page after process is again displayed. Thus, the entire finished state after a desired process is specified and performed can be efficiently displayed with a simple operation. With this, a user interface device with high operability can be achieved.

Furthermore, in the user interface device according to the first embodiment, the split-area information has already been generated by the trimming generating unit 12 before an area is selected from among the displayed area icons. Therefore, when an area icon is specified, the time for generating a split preview image can be reduced, thereby allowing an instantaneous menu display with split preview images.

A user interface device according to a second embodiment of the present invention is different from that according to the first embodiment in that the operation displaying unit 15 displays a preview image and area icons, then a specification is first received from among the displayed area icons, and then the trimming generating unit 12 generates split-area information corresponding to the specified area icon. That is, in the case of the first embodiment, the split-area information has already been generated by the trimming generating unit 12 before an area is selected from among the displayed area icons. By contrast, in the second embodiment, the trimming generating unit 12 generates split-area information after an area is specified from among the area icons.

A functional block diagram of the user interface device according to the second embodiment is similar to FIG. 1, which is the functional block diagram of the user interface device according to the first embodiment, and therefore is not shown.

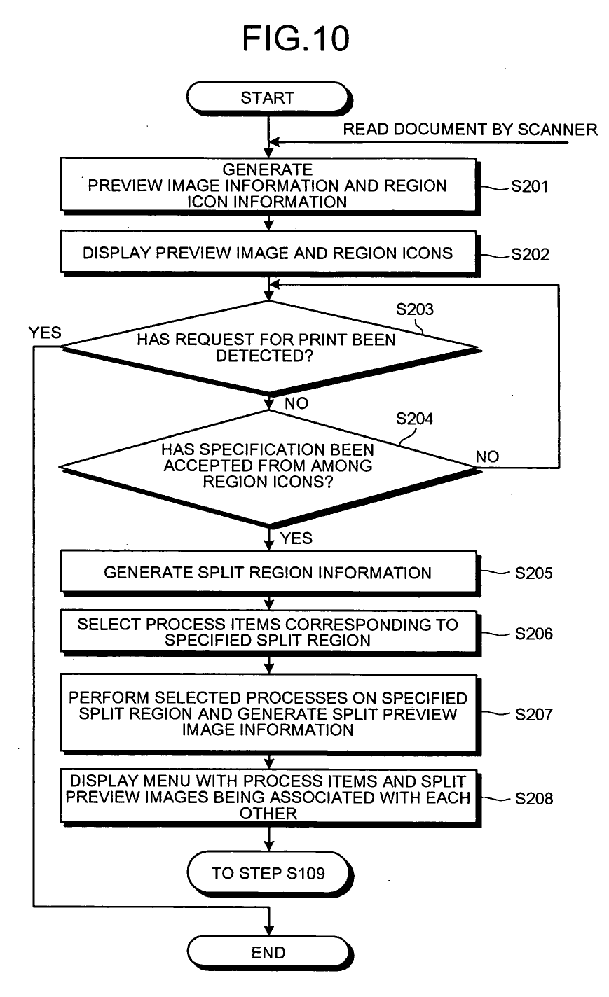

FIG. 10 is a flowchart for explaining a procedure of displaying split preview images according to the second embodiment. In the case of the second embodiment, after the preview generating unit 11 generates preview image information for displaying input information and area-icon information indicative of split areas obtained by splitting a preview image (step S201), the operation displaying unit 15 displays the preview image information and area icons (step S202).

The operation displaying unit 15 is ready for detecting a request for print (step S203). If the operation displaying unit 15 has detected such a request (“Yes” at step S203), the procedure ends for printing.

If the operation displaying unit 15 does not detect a request for print (“No” at step S203), the operation displaying unit 15 detects whether a specification has been received from among area icons (step S204). If the operation displaying unit 15 does not detect such a specification, the procedure returns to step S203.

If the operation displaying unit 15 has detected that a specification has been received from among the area icons (“Yes” at step S204), the trimming generating unit 12 generates split-area information only for a split area corresponding to the specified area icon (step S205). This is different from the first embodiment.

The item selecting unit 13 then selects process items corresponding to the specified split area (step S206). The split-preview generating unit 14 performs the selected processes on the specified split-area information and generates split preview image information for each process (step S207), with the process items as tags being concurrently displayed with the split preview images (step S208). Thereafter, the procedure is similar to step S109 in the first embodiment, and therefore is not explained.

In this manner, according to the user interface device of the second embodiment, a preview image and area icons are first displayed. When a specification is received from among the displayed area icons, the trimming generating unit 12 generates only information about a split area corresponding to the specified area icon. Therefore, there is no waste in split area generation. With this, a user interface device with high operability can be achieved.

Also, after an area is selected from among the displayed area icons, the trimming generating unit 12 generates split-area information. Therefore, only the split-area information of a required portion is generated when required, and split preview images are displayed. Therefore, the load on the Central Processing Unit (CPU) can be distributed, thereby allowing an immediate operation after updating the preview image.

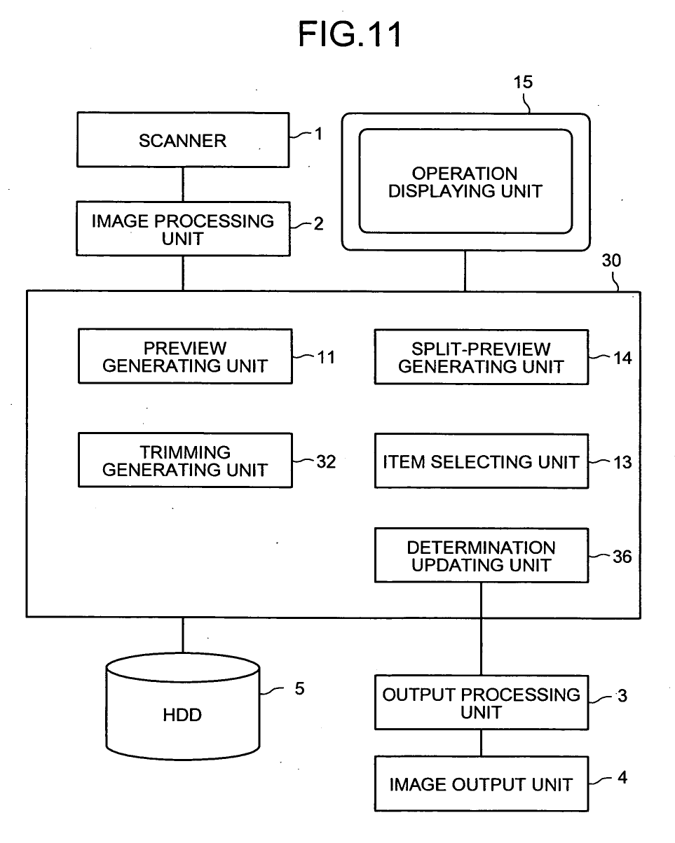

FIG. 11 is a functional block diagram of an image forming apparatus having incorporated therein a user interface device 30 according to a third embodiment of the present invention. The user interface device 30 according to the third embodiment is different from that according to the second embodiment in that a determination updating unit 36 is further provided that determines whether split-area information specified through area icons has already been generated.

A trimming generating unit 32 stores in the HDD 5 split-area information already generated. The determination updating unit 36 detects whether the split-area information specified through the area icons has already been stored in the HDD 5. If it is determined that the split-area information has not been generated, the trimming generating unit 32 generates split-area information corresponding to the specified area icon.

On the other hand, if the determination updating unit 36 detects the split-area information stored in the HDD 5 and determines that it has already been generated, the latest one of the generated and stored split-area information is read for transmission to the trimming generating unit 32.

The split-preview generating unit 14 performs processes indicated by the process items selected by the item selecting unit 13 on the split-area information obtained by the trimming generating unit 32, and then causes the operation displaying unit 15 to display a menu with the split preview image information, which represents split area images after these processes, and the process items being associated with each other.

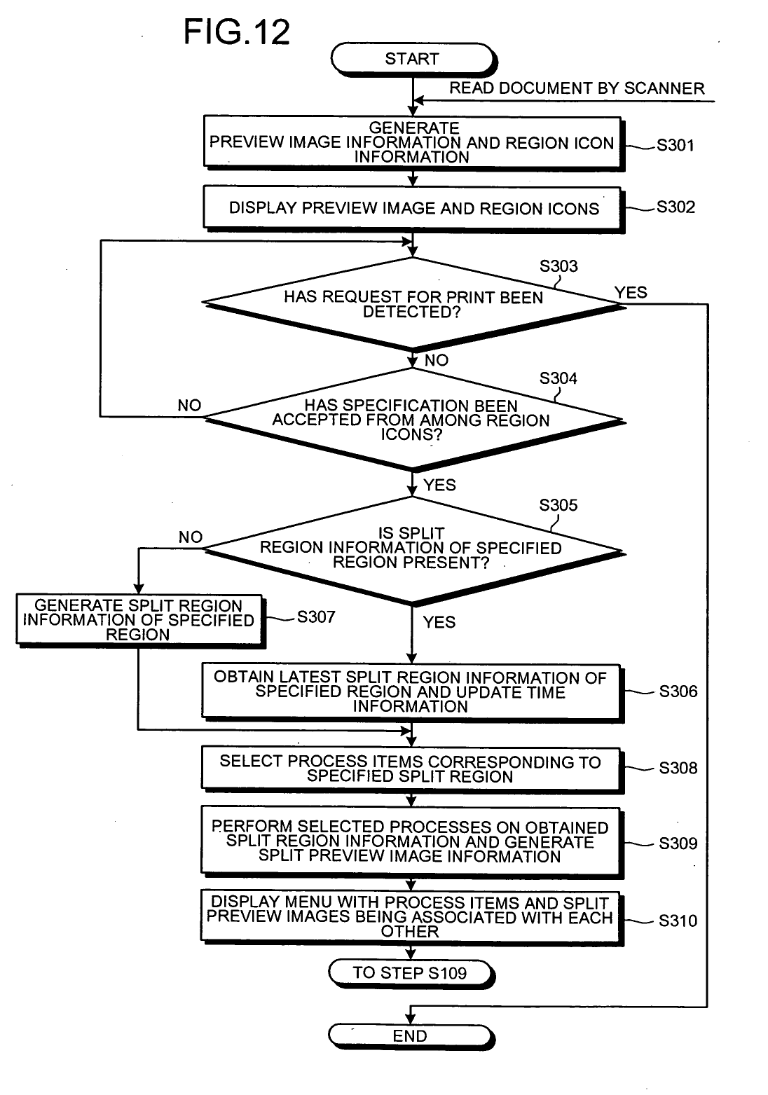

FIG. 12 is a flowchart for explaining a procedure of displaying split preview images according to the third embodiment. Steps S301 to S304 are similar to steps S201 to S204 in the second embodiment, and therefore are not explained.

If the operation displaying unit 15 has received a specification from among the area icons (“Yes” at step S304), the determination updating unit 36 determines whether split-area information of the area corresponding to the specified area icon has been stored in the HDD 5 (step S305). If it is determined that split-area information has not been stored (“No” at step S305), the trimming generating unit 32 generates split-area information of the specified area (step S307).

On the other hand, if it is determined that split-area information has been stored (“Yes” at step S305), the determination updating unit 36 obtains the latest split-area information corresponding to the specified area icon from the HDD 5, updates time information of this split-area information, and then transmits it to the trimming generating unit 32 (step S306). In this manner, irrespectively of the determination result of the determination updating unit 36, the trimming generating unit 32 obtains the information about the specified split area.

Step S308 and onward are similar to step S206 and onward in the second embodiment, and therefore are not explained.

In this manner, according to the user interface device of the third embodiment, if split-area information specified from among the area icons has already been generated, this split-area information is used. Therefore, at the time of selecting a split area on the preview image, if the latest information about this split area is already present, the latest information is used. If not present, split-area information is generated at this time. Therefore, the load on the CPU is distributed.

The preview generating unit 11 can be configured not only to split the preview image into nine split areas, but also to set the number of split areas. This is because such setting is possible as appropriated for achieving high operability according to the input information, an increase or decrease of the setting items, and other factors.

Also, the preview generating unit 11 can be configured to generate process items for setting so that they are displayed at positions away from the split preview images, and the operation displaying unit 15 can be configured to display the process items generated by the preview generating unit 11 for receiving a setting from among the displayed process items. This is because there may be the case where a specification from a place other than the menu display with the split preview images is convenient.

Furthermore, on the menu display with the split preview images, when process items are selected, the selected items and their split preview images are preferably on highlighted display. On the contrary, unselected process items and their split preview images are preferably displayed as being subjected to a blackout process. In both cases, the selected process items and their preview images can be visually recognized with ease.

Moreover, as a menu display, a display scheme has been mainly explained in which a process is performed on a split area obtained by partially trimming the preview image. This area splitting can allow overlapping.

Furthermore, a process may be performed on the preview image itself for menu display. In this case, with overlapping display, a preview display is produced with only parts being overlapped in practice. Therefore, the process results can be partially set out for comparison.

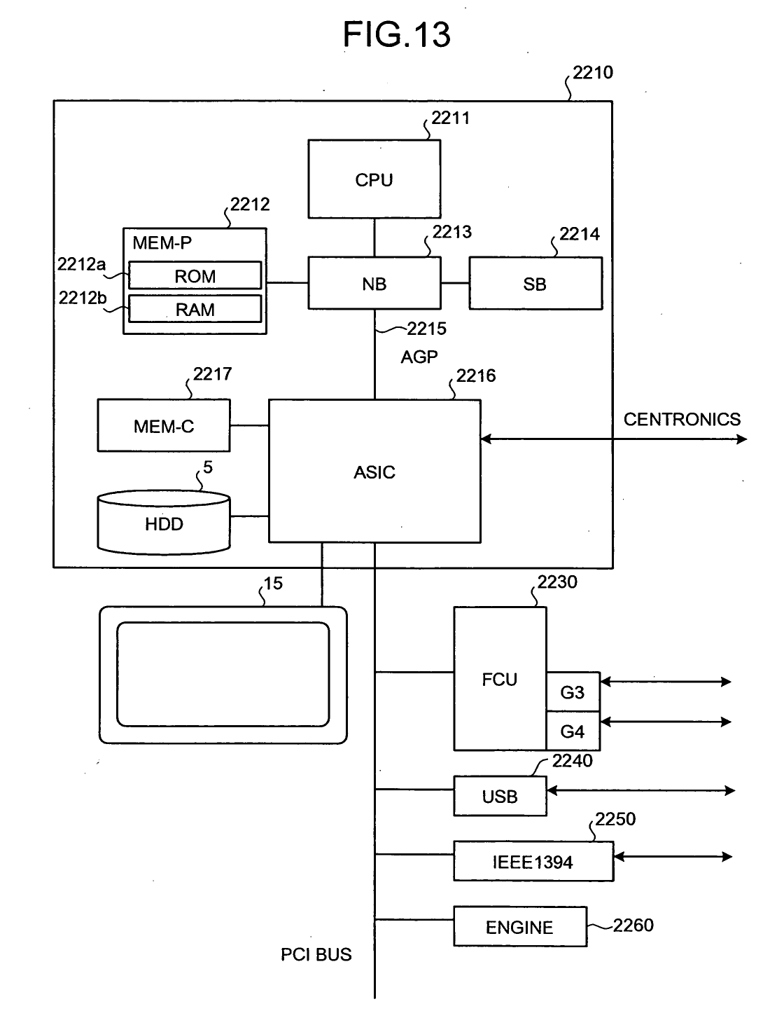

FIG. 13 is a block diagram of a hardware configuration of an image forming apparatus having incorporated therein the user interface device according to the present invention. The image forming apparatus is configured to be a Multifunction Product (MFP) with multifunction, such as facsimile and scanner functions. As shown in the drawing, this MFP is configured with a controller 2210 and an engine unit 2260 being connected to each other via a Peripheral Component Interconnect (PCI) bus. The controller 2210 is a controller that controls an input from an FCU I/F 2230 and the operation displaying unit 15 by performing, for example, control over the entire MFP, image display control, various controls, and image processing control. The engine unit 2260 is an image processing engine connectable to the PCI bus, and includes, for example, image processing portions for error diffusion, gamma transformation on the obtained image data, and others.

The controller 2210 includes a Central Processing Unit (CPU) 2211, a northbridge (NB) 2213, a system memory (MEM-P) 2212, a southbridge (SB) 2214, a local memory (MEM-C) 2217, an Application Specific Integrated Circuit (ASIC) 2216, and the HDD 5, with the NB 2213 and the ASIC 2216 being connected therebetween with an Accelerated Graphics Port (AGP) bus 2215. Also, the MEM-P 2212 further includes a Read Only Memory (ROM) 2212a and a RAM 2212b.

The CPU 2211 performs controls over the entire MFP, includes a chip set formed of the NB 2213, the MEM-P 2212, and the SB 2214, and is connected to other devices via this chip set.

The NB 2213 is a bridge for connection of the CPU 2211 with the MEM-P 2212, the SB 2214, and the AGP bus 2215, and includes a memory controller that controls reading and writing with respect to the MEM-P 2212, a PCI master, and an AGP target.

The MEM-P 2212 is a system memory for use as, for example, a memory for storing programs and data or a memory for developing programs and data, and includes the ROM 2212a and the RAM 2212b. The ROM 2212a is a read-only memory for use as a memory for storing programs and data, whilst the RAM 2212b is a writable and readable memory for use as, for example, a memory for developing programs and data or an image rendering memory at the time of image processing.

The SB 2214 is a bridge for connection of the NB 2213 with PCI devices and peripheral devices. The SB 2214 is connected to the NB 2213 via the PCI bus. To this PCI bus, the FCU I/F 2230 is also connected, for example.

The ASIC 2216 is an Integrated Circuit (IC) dedicated to multimedia information processing, contains hardware components for multimedia information processing, and serves as a bridge for connecting the AGP bus 2215, the PCI bus, the HDD 5, and the MEM-C 2217.

The ASIC 2216 includes a PCI target, an AGP master, an arbiter (ARB), which is a core of the ASIC 2216; a memory controller that controls the MEM-C 2217, and a plurality of Direct Memory Access Controllers (DMACs) for image data rotation and others by a hardware logic and others. Between these components included in the ASIC 2216 and the engine unit 2260 via the PCI bus, a Universal Serial Bus (USB) 2240, and the Institute of Electrical and Electronics Engineers (IEEE) 1394 interface 2250 are connected.

The MEM-C 2217 is a local memory for use as an image buffer for transmission or a coding buffer. The HDD 5 is a storage for storing image data, programs, font data, and forms.

The AGP bus 2215 is a bus interface for a graphics accelerator card suggested for increasing the speed of graphic processing, and increases the speed of the graphics accelerator card by directly accessing the MEM-P 2212 with a high throughput.

The operation displaying unit 15 connected to the ASIC 2216 receives an operation input from the operator, and transmits the received operation input information to the ASIC 2216.

Note that the image processing program executed on the MFP having incorporated therein the user interface device according to the embodiments is provided as being previously incorporated in a ROM or the like.

The menu displaying program executed on the MFP having incorporated therein the user interface device according to the embodiments may be configured to be provided as being recorded in an installable format or an executable format on a computer-readable recording medium, such as a Compact-Disk Read-Only Memory (CD-ROM), a flexible disk (FD), a Compact-Disk Recordable (CD-R), or a Digital Versatile Disk (DVD).

Furthermore, the menu displaying program executed on the MFP having incorporated therein the user interface device according to the embodiments may be configured to be provided as being stored on a computer connected to a network, such as the Internet, and then being downloaded via the network. Also, the menu displaying program executed on the MFP having incorporated therein the user interface device according to the embodiments may be provided or distributed through a network, such as the Internet.

The menu displaying program executed on the MFP having incorporated therein the user interface device according to the embodiments has a module configuration including each of the components explained above (the preview generating unit 11, the trimming generating unit 12, the item selecting unit 13, the split-preview generating unit 14, the operation displaying unit 15, the determination updating unit 36, and others). As actual hardware, with the CPU (processor) reading the menu displaying program from the ROM for execution, each unit explained above is loaded onto a main storage device, thereby generating thereon the preview generating unit 11, the trimming generating unit 12, the item selecting unit 13, the split-preview generating unit 14, the operation displaying unit 15, the determination updating unit 36, and others.

The embodiments and modification examples of the present invention explained above are merely by way of example, and the present invention is not restricted to these specific examples explained herein.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A user interface device comprising:
an operation displaying unit that displays thereon a preview image of an input image and receives a specification of a position on displayed preview image;
an item selecting unit that selects at least two process items corresponding to a display position of the displayed preview image based on specified position on the displayed preview image;
a preview generating unit that generates a new preview image obtained by performing selected at least two processes on the input image; and
a preview displaying unit that displays generated preview image on the operation displaying unit in a menu format.

2. The user interface device according to claim 1, wherein
the preview generating unit generates a split preview image by performing the selected at least two processes on split-area information defined by the specified position.

3. The user interface device according to claim 2, wherein
the preview generating unit generates the split-area information before the operation displaying unit receives the specification of the position.

4. The user interface device according to claim 2, wherein
the preview generating unit generates the split-area information defined by the specified position after the operation displaying unit receives the specification of the position.

5. The user interface device according to claim 2, wherein
the preview generating unit includes a determining unit that determines whether the split-area information defined by the specified position already exists, and
after the operation displaying unit receives the specification of the position, if the determining unit determines that the split-area information corresponding to the specified position does not exist, the preview generating unit generates the split-area information corresponding to the specified position.

6. The user interface device according to claim 1, wherein
the preview generating unit performs the selected processes on the input image when a specification of the preview image displayed in the menu format is received through the operation displaying unit, and
the preview displaying unit further displays processed preview image.

7. The user interface device according to claim 2, wherein
the preview generating unit generates an area icon corresponding to the split-area information on the displayed preview image, and
the item selecting unit receives the specification of the position through displayed area icon.

8. The user interface device according to claim 1, wherein
the preview generating unit generates the process items corresponding to each preview image in a format of a tag.

9. The user interface device according to claim 8, wherein
the preview generating unit generates the process items in such a manner that a part of a frame surrounding the split preview image is protruding as the tag.

10. The user interface device according to claim 2, wherein
the preview generating unit generates the split preview image in such a manner that split preview images partially overlap in a predetermined direction.

11. The user interface device according to claim 8, wherein
the preview generating unit generates a split preview image by performing the selected at least two processes on split-area information defined by the specified position, and
the preview generating unit generates the split preview image in such a manner that process item information of the tag is not hidden.

12. The user interface device according to claim 2, wherein
the preview generating unit splits the preview image into nine areas including three areas in a vertical direction and three areas in a horizontal direction.

13. The user interface device according to claim 1, wherein
the preview generating unit generates the process items separately from the preview image, and
the item selecting unit receives a setting from the process items displayed separately from the preview image.

14. The user interface device according to claim 1, wherein
the operation displaying unit includes a touch panel for receiving a touch input.

15. A method of displaying a preview image, the method comprising:
receiving a specification of a position on a preview image of an input image displayed on an operation displaying unit;
selecting at least two process items corresponding to a display position of displayed preview image based on specified position on the displayed preview image;
generating a new preview image obtained by performing selected at least two processes on the input image; and
displaying generated preview image on the operation displaying unit in a menu format.

16. A computer program product comprising a computer usable medium having computer readable program codes embodied in the medium that when executed cause a computer to execute:
receiving a specification of a position on a preview image of an input image displayed on an operation displaying unit;
selecting at least two process items corresponding to a display position of displayed preview image based on specified position on the displayed preview image;
generating a new preview image obtained by performing selected at least two processes on the input image; and
displaying generated preview image on the operation displaying unit in a menu format.
